(19) United States
(12) Patent Application Publication
(10) Pub. No.: US 2016/0047855 A1
(43) Pub. Date: Feb. 18, 2016

(54) PCB AUTHENTICATION AND COUNTERFEIT DETECTION

(71) Applicant: Case Western Reserve University, Cleveland, OH (US)

(72) Inventors: Swarup Bhunia, Beachwood, OH (US); Fengchao Zhang, Cleveland, OH (US); Yu Zheng, Cleveland Heights, OH (US); Andrew Hennessy, Cleveland, OH (US)

(21) Appl. No.: 14/828,305

(22) Filed: Aug. 17, 2015

Related U.S. Application Data
(60) Provisional application No. 62/037,959, filed on Aug. 15, 2014.
(60) Provisional application No. 62/081,732, filed on Nov. 19, 2014.

(51) Int. Cl. G01R 31/28; G01R 31/317

(52) U.S. Cl. CPC G01R 31/281; G01R 31/31703

(57) ABSTRACT

This disclosure relates generally to printed circuit board authentication, such as for protecting printed circuit boards against counterfeiting. The authentication can be implemented based on measurements from the PCB used to generate a unique signature for the PCB. The generated signature of the PCB can be evaluated to determine if the PCB is authentic or counterfeit.

### CROSS-REFERENCE TO RELATED APPLICATIONS

This application claims the benefit of U.S. provisional patent application No. 62/037,959 filed on Aug. 15, 2014 and entitled PCB AUTHENTICATION AND COUNTERFEIT DETECTION, and U.S. provisional patent application No. 62/081,732 filed on Nov. 19, 2014 and entitled PCB AUTHENTICATION AND COUNTERFEIT DETECTION, each of which is incorporated herein by reference in its entirety.

### TECHNICAL FIELD

This disclosure relates generally to printed circuit board authentication, such as for protecting printed circuit boards against counterfeiting.

### BACKGROUND

A printed circuit board (PCB) mechanically supports and electrically connects electronic components using conductive tracks, pads and other features etched from copper sheets laminated onto a non-conductive substrate. PCBs can be single sided (one copper layer), double sided (two copper layers) or multi-layer. PCBs may be populated with components, such as capacitors, resistors or active devices (e.g., integrated circuit chips) attached to or embedded in the substrate.

The increasingly complex global semiconductor supply chain, spanning different countries and their legal systems to meet the ever-rising demand, provides ample opportunities for adversaries to insert counterfeit chips in the market. Prior to actual deployment, an IC is often bought and resold many times. Purchasers rely on brokers, who in turn may buy from untrustworthy entities including online forums.

### SUMMARY

This disclosure relates generally to printed circuit board authentication and counterfeit detection.

As one example, a method for authenticating a printed circuit board (PCB) includes measuring electrical parameters for each of a plurality of paths of the PCB. The method also includes determining values based on the measured electrical parameters for each of the plurality of paths of the PCB. The method also includes generating a signature for the PCB based on at least a portion of the determined values to uniquely identify the PCB.

As another example, a method includes, for a plurality of paths of a printed circuit board (PCB), selecting one of the plurality of paths of the PCB, connecting a pair of probes to spaced apart electrical conductors corresponding to the selected path, using the connected probes to measure electrical impedance for the selected path, and determining a value for the selected path based on the measured electrical impedance. The method also includes generating a signature based on at least a portion of the determined values for the plurality of paths to uniquely identify the PCB and storing the generated signature.

As yet another example, a method includes providing a populated printed circuit board (PCB) that includes a plurality of Joint Test Action Group (JTAG) compliant components mounted to the PCB. The PCB includes a plurality of electrically conductive paths between boundary scan cells within at least some of the components and paths connected between different ones of the components. The method also includes connecting a test probe to a JTAG port on the PCB. The method also includes measuring a temporal parameter for each of a plurality of paths based on signals detected at the JTAG port via the test probe. The method also includes generating a signature based on the measured temporal parameters for a selected set of the plurality of paths to uniquely identify the PCB.

### BRIEF DESCRIPTION OF THE DRAWINGS

FIG. 1 is a flow diagram depicting an example method.

FIG. 2 depicts an example of a system that can be used for PCB authentication and counterfeit detection.

FIG. 3 is a flow diagram depicting an example of a signature generation procedure.

FIG. 4(a) is a side elevation depicting an example of a schematic of measurement setup for a PCB.

FIG. 4(b) depicts an example of a measurement setup.

FIGS. 5(a) and 5(b) illustrate examples of inter-PCB hamming distance (HD) and intra-PCB HD that can be generated.

FIGS. 6(a) and 6(b) illustrate examples of inter-PCB HD and intra PCB HD for a different setup.

FIG. 7 illustrates an example PCB authentication pattern that includes a sequence of multiple test paths.

FIG. 8 illustrates an example histogram for a test path in FIG. 7.

FIG. 9 illustrates an example histogram for another test path in FIG. 7.

FIG. 10 illustrates an example histogram for yet another test path in FIG. 7.

FIG. 11 illustrates an example histogram for still another test path in FIG. 7.

FIG. 12(a) depicts an example of a JTAG based boundary scan architecture in a PCB that can be employed for PCB authentication.

FIG. 12(b) depicts an example of a structure of a boundary scan cell.

FIG. 13 illustrates an example of a JTAG-based PCB authentication method.

FIG. 14 illustrates an example of a state machine of a TAP controller.

FIG. 15 illustrates an example of timing for JTAG pins that can be implemented using PCB authentication.

FIG. 16(a) illustrates an example of the connection of BSCs in state ‘SHIFT DR’.

FIG. 16(b) illustrates an example creating a clock pulse with period tₘₑₐₛ for scan path delay measurements.

FIG. 17 illustrates the timing of test signals for delay measurement in two successive iterations.

FIG. 18(a) illustrates an example architecture of the proposed PSDM unit for BSC path delay characterization.

FIG. 18(b) illustrates an example of clock generation procedure for PSDM.

### DETAILED DESCRIPTION

This disclosure relates to authentication for printed circuit boards (PCBs), such as can be implemented to help reduce counterfeiting of PCBs. The authentication can be implemented as including a method, system and/or as machine readable instructions. As disclosed herein, the approach can be implemented by any number of PCB manufacturers or their associates to generate unique signatures to identify PCBs. The unique signature for each PCB can be generated based on measured electrical characteristics for a selected sequence of electrical paths in each respective PCB. The signatures can be stored in one or more databases, which are accessible to authorized users (e.g., via secure logon). Another entity in a supply chain for the PCB or devices utilizing such PCB as well as end users of such PCB or devices can measure electrical characteristics for the PCB (e.g., for the same sequence of paths) and generate a signature based on such measurements to evaluate the authenticity of the PCB. For example, if the generated signature matches (e.g., within a sufficient statistical certainty) a predetermined signature provided by the PCB manufacturers or another trusted source (e.g., stored in a database), the PCB can be categorized as authentic. If the user-generated signature does not match a predetermined signature, the PCB can be categorized as counterfeit.

As one example, a signature for a given PCB can be generated based on impedance measurements obtained from a plurality of electrically conductive traces of the given PCB. Since the impedance of the traces in the PCB vary for each PCB according to intrinsic properties and manufacturing process variations, the impedance measurements can individually as well as collectively correspond to physically unclonable functions (PUF) not practically reproducible by counterfeiters. The measurements can be made by readily available test equipment, such as including multimeter or ohm-meter, for example. A set of paths can be selected such that the same set of paths can used for generating signatures for subsequent authentication. The probes of the test system can be connected to electrical conductors to enable measuring the impedance of a given one of the selected paths. The probe placement and measurements can be done manually, semi-automatically or fully automatically by the test system. The measurements for the selected paths can also be made in a predefined sequence of measurements for generating the signature for the PCB. A value for each selected path can be determined based on the measured electrical impedance for each such path. A corresponding signature can be generated based on at least a portion of the determined impedance values for the plurality of paths to uniquely identify the PCB.

As another example, a signature for a given PCB can be generated based on time delay measurements for signals to propagate through a plurality of paths of the given PCB. For instance, the PCB can include a plurality of Joint Test Action Group (JTAG) compliant components mounted to the PCB configured to perform boundary-scan operations, thereby making the PCB itself JTAG compliant. As used herein, JTAG compliant can refer to the integrated circuit technologies that comply with the IEEE's standard entitled Boundary Scan Architecture—Standard Test Access and Boundary Scan Architecture WG P1149.1. Examples of such technologies are available from JTAG Technologies Inc. of Stevensville, Md.

The PCB thus can include a plurality of electrically conductive paths between boundary scan cells within JTAG compliant components as well as electrically conductive paths connected between different components. The various paths can be accessible by connecting a test probe to a JTAG port of the PCB. The test probe can be used to measure a temporal parameter for a plurality of the paths based on signals detected at the JTAG port. For example, the temporal parameter can be a time delay for signals to propagate through a respective path. A corresponding signature can be generated based on the temporal parameters for a selected set of the plurality of paths to uniquely identify the PCB. As in the previous example, the signature can be evaluated to determine the authenticity of the PCB. In some cases, multiple approaches disclosed herein can be combined to generate a signature based on a selected set of impedance values and temporal parameters.

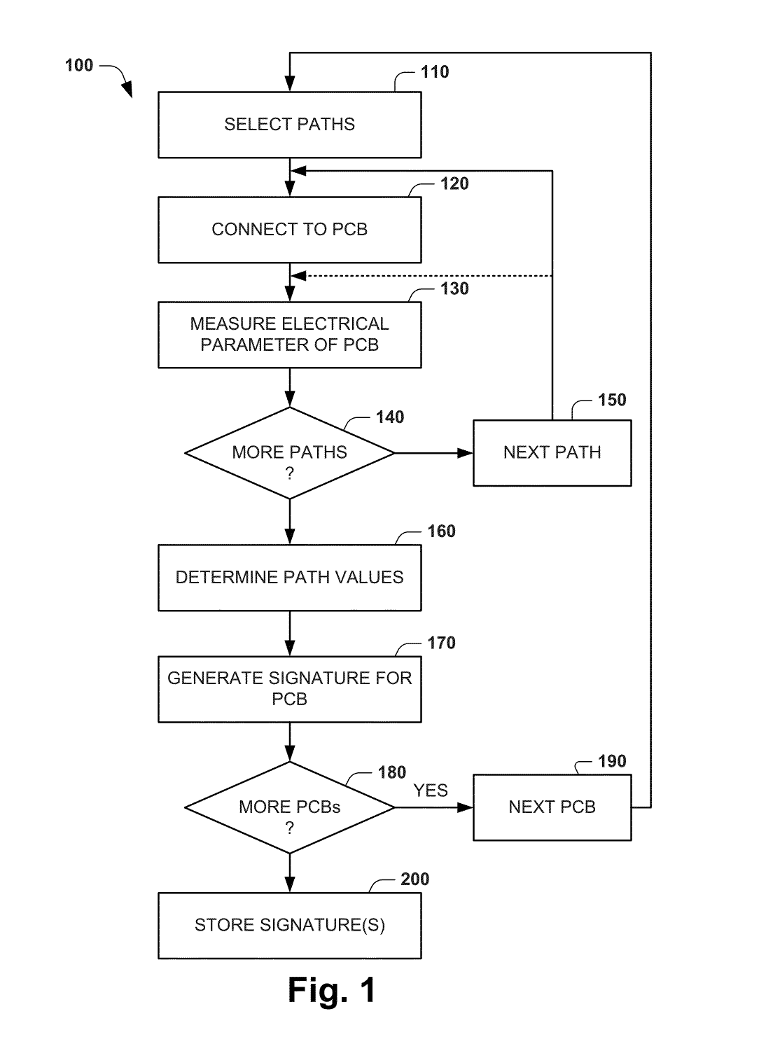

FIG. 1 depicts an example of a method that can be implemented for authenticating one or more PCB's. It is to be understood and appreciated that the illustrated actions, in other embodiments, may occur in different orders or concurrently with other actions. For example, values can be determined when each measurement is made for a respective PCB. Moreover, not all features illustrated in FIG. 1 may be required to implement a method. It is to be further understood that the following method can be implemented in hardware (e.g., one or more processors, such as in a computer, field programmable gate array (FPGA), or an application specific integrated circuit), software (e.g., stored in a computer readable medium or as executable instructions running on one or more processors), or as a combination of hardware and software. For example, the method 100 can be implemented using a test system that can be activated in response to a user input to automatically or semi-automatically perform various actions, as disclosed herein. A given PCB can include a plurality of electrically conductive paths, each of which can provide unique electrical characteristics for the path. For instance, the unique electrical characteristics can correspond to inherent characteristics of the path, such as can vary due manufacturing process variations or other intrinsic properties of materials that are used.

At 110 to select a given path which extends between respective endpoints. As such, a collection of these paths selected at 110 can be utilized to generate a signature for uniquely identifying a PCB. For instance, the electrical properties or characteristics that are measured for each of the paths (at 130) can represent physical unclonable functions (PUF) for the PCB. As disclosed herein, the paths selected at 110 can each have corresponding electrical parameters or characteristics that depend on process variations and/or intrinsic properties of the particular materials utilized in the corresponding manufacturing process implemented by the manufacturer of such PCB.

At 120, one or more connections can be made to the PCB. For example, a test system can include probes that physically connect with electrical conductors on the PCB such as disclosed herein. The connection can be a manual connection performed by a person and/or automatically by a robot. At 130, an electrical parameter or parameters can be measured for a selected path of the PCB based upon the connection at 120. As an example, the electrical parameter can include impedance (e.g., resistance, capacitance and/or inductance), voltage, current as well as temporal parameters, such as timing and propagation of signals as an example. The measured electrical parameters for the selected path can be stored in memory accessible by the test system for subsequent processing, as disclosed herein.

As used herein, a path can include one or more electrical traces on the PCB, which may extend along a single layer or pass through multiple layers. Additionally or alternatively, a given path can also correspond to a path within an integrated circuit chip and/or other components that are mounted to the PCB. As an example, a path can include a path between boundary scan cells for a JTAG compliant device, which can be accessed via a JTAG test and programming port (TAP).

At 140, a determination can be made as to whether any additional paths in the selected paths 110 exist for obtaining measurements. As mentioned, the set of paths can be preselected so that measurements are obtained for a predetermined set of paths, which measurements may be acquired in a predefined sequence. If the determination is positive (YES), indicating that additional paths exists, the method can proceed to 150 in which the next path is identified. From 150 the method can return to 120 in which a connection can be made to the PCB corresponding to the next path that is identified at 150. In other examples, such as where the existing connection to the PCB at 120 is sufficiently configured to obtain information about the next path without reconnecting to the PCB, the method can proceed from 150 to 130 without physically modifying the connection to the PCB. An example where such connection can be sufficient is where the connection is made to a JTAG TAP interface of the PCB.

The method thus can loop between 120 and 150 for each of the plurality of selected paths to acquire measurements from the PCB. It is to be understood and appreciated that the order in which the selected paths are measured can be a predetermined sequence of such paths. After the measurements have been made for the entire set of selected paths, at 140, upon the determination indicating that no additional paths exist, the method can proceed to 160.

At 160 path values can be determined. In some examples, each of the path values determined at 160 can be determined for a single respective one of paths. Additionally or alternatively, some of the path values can correspond to an aggregate path value computed based on measurements for two or more paths. For example, a given path value can be computed as a difference (or another mathematical and/or combinatorial function) between measurements for adjacent paths according to a sequence in which the respective measurements at 130 are made. The path values can correspond to digitized values of the measured parameters at 130, such as can be normalized to a predefined scale. For example, impedance measurements can be scaled between zero and one. In another example, time delays for a single propagation between two electrical components over a corresponding one of the paths can be computed and converted to a digitized value representing the delay time.

At 170, a signature for the PCB can be generated based on at least a portion of the path values determined at 160. The generated signature can be stored in memory, locally or remotely via a network connection. For example, the signature for the PCB can be generated at 170 based on a selected subset of the path values determined at 160. Additionally, the signature generated at 170 can be based on the predetermined subset of path values for paths arranged in a predefined sequence of paths so that the generated signature corresponds to a particular sequence of paths and is derived based upon the measured parameters for each such paths. As an example, the generated signature can include 256 bits or another number of bits can be used. For instance, the value of each path can correspond to a corresponding bit or a predetermined number of bits concatenated together in a predetermined order to form the resulting signature. The order in which the path values are concatenated can be the order in which measurements were made or some other prescribed order to provide the signature. The order can be known a priori and will generally depend on whether the method 100 is being performed by the manufacturer for generating the initial signature values that will be the gold standard for evaluating authenticity or the method is performed by a user of the PCB (e.g., end user or user at any other stage in the PCB supply chain).

When the method is utilized by a manufacturer or other user with respect to a plurality of PCBs, the method can include another determination at 180 as to whether any additional PCBs exist for which the method is to be applied. If more PCB's exist the method can proceed to 190 where the next PCB is prepared and loaded for processing according to the method. From 190 the method can return to 110, and the method is repeated for such PCB. Where the PCB is the same type of PCB and includes the same paths, the method can proceed from 190 directly to 120 for processing and signature generation.

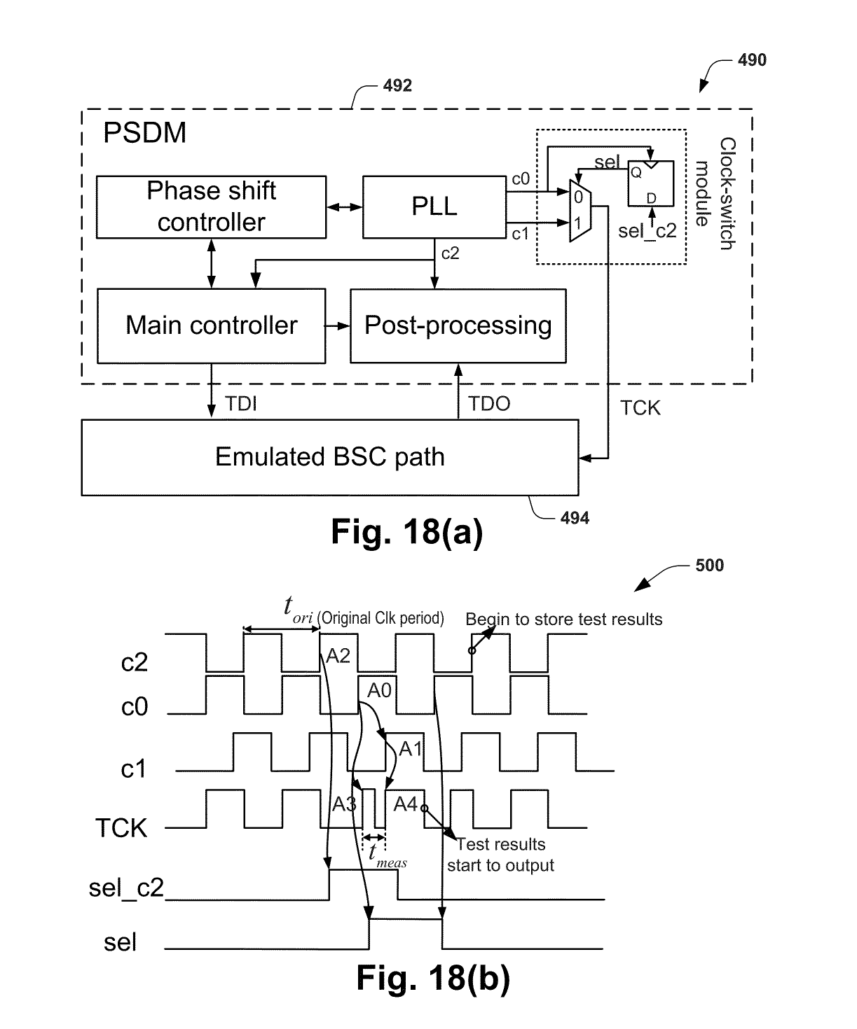

Once no additional PCBs exist, the method can proceed from 180 to 200 in which the signatures that have been generated can be stored in memory associated with each PCB. For example, where a manufacturer generates signatures for PCBs that it has generated, the signatures can be stored in a database that can be accessed by other users for determining the authenticity of each of the PCBs (see, e.g., FIG. 18). That is, since each PCB has a unique signature that has been generated at 170 (and linked to the signature in the manufacturer's database, the subsequent user (e.g., at any stage of a supply chain) can verify the authenticity of the PCB by implementing similar steps by measuring the electrical parameters of the PCB and generating a signature for the subset of paths in the same manner as performed by the manufacturer. In some cases, the user will be provided with instructions to follow for generating the signature using standard measurement/test equipment. In other examples, the manufacturer can provide proprietary equipment to which each PCB can be connected for performing the measurements. Thus, once a signature has been generated, a look-up can be performed with respect to the database of signatures to ascertain whether the manufacturer or other trusted entity has a match within a statistically sufficient proximity.

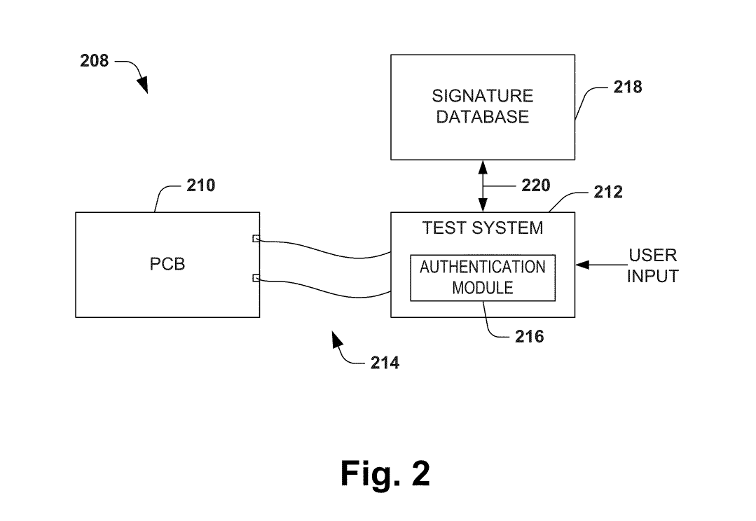

As a further example, FIG. 2 depicts an example of system 208 that can be utilized for authenticating a PCB 210. The system 208 includes a test system 212 that can be connected to the PCB 210 via a link 214. In this example, the link 214 can be implemented as a physical link; however, the communication link between the system and the PCB can include wireless communication links in other examples.

The test system 212 can include an authentication module 216. The authentication module can be implemented as hardware and/or software, which is programmed to implement the method 100 of FIG. 1 or at least a portion thereof depending upon the purpose of the test system 212. For example, the test system 212 can be utilized by a manufacturer (or other trusted entity in the PCB supply chain) to generate a signature database 218 that includes signatures generated for a plurality of PCB's such as disclosed herein. In other examples, the test system 212 and the authentication module 216 can be implemented by a user (e.g., downstream in the supply chain from the entity generating the signature) who wishes to confirm the authenticity of the PCB 210 by generating a signature for the PCB, such as disclosed herein.

While, in the example of FIG. 2, the test system 212 is demonstrated as connected to the PCB via link 214, in other examples, the test system and authentication module 216 can be integrated into the PCB 210 or into a device that includes the PCB (e.g., a set-top box, a gaming console, a drone, a home monitoring device or other internet-of-things (IoT) device) that includes network connectivity. In this example, the test system 212 and authentication module 216 can be configured to perform autonomous authentication of the PCB 210 (or of multiple PCBs within the device) by accessing the remote signature database 218 using the devices network interface. This can be done one as part of an initial boot-up process or intermittently at periodic or random time intervals or in response to a command trigger sent to such device remotely from a service. The autonomous authentication and testing thus provides a mechanism to detect in-field tampering, such as altering or disabling provider/manufacturer-imposed restrictions of computers or entertainment devices.

For example, the authentication module 214 of the test system 212 can be programmed to execute machine readable instructions from a provider (e.g., a manufacturer) of the PCB 210 to measure (or cause to be measured) electrical parameters (e.g., resistance, time delays or the like) for a set of circuit paths. In some examples, the test system can include a measurement system that performs the measurements of the electrical parameters. In other examples, the measurement system can be a separate system that interfaces with the test system to supply measurements made, which can be automated in response to machine readable instructions from the authentication module and/or manually implemented by a human operator. The authentication module 216 thus can aggregate a set of the electrical parameter measurements to provide a corresponding signature.

The authentication module 216 can evaluate the corresponding signature relative to a signature database 218 to confirm the authenticity of the PCB, such as disclosed herein. The signature database 218 can be local (e.g., in local memory or memory in a local network) or accessible via a communications link 220 (e.g., via one or more network). The test system 212 accesses the signature database to determine whether the signature generated for the PCB from the electrical measurements represents an authentic or counterfeit PCB (e.g., a cloned PCB or one that has been modified/tampered with). Since the signature can represent physically unclonable functions (PUFs) for the PCB, the signature database can be public, such as be made available over the internet. In other examples, the manufacturer who maintains the signature database 218 can employ encryption or other security mechanisms (e.g., provide a secure communications tunnel at 220) for accessing the signature database 218 by the test system 212. In some examples, the signature database can be implemented as a trusted service that can be configured to authenticate the signature generated by the authentication module. That is, the authentication function can be distributed between the test system and signature database 218.

For example, the authentication module 216 can generate the corresponding signature for the PCB, send it to a remote server (e.g., at a predefined resource location, such as a URL) via a secure link (e.g., implemented as https, SSL or other secure communications protocol) 220. The remote server employing the database 218 can evaluate the signature and send a response back to the test system via the link 220 specifying whether the PCB is authentic or not (e.g., if it has been tampered with or is counterfeit).

By way of further example, JTAG-based PCB authentication, which captures information about the intrinsic properties of the hardware encompassing both the chips and metal traces in a PCB while forming signature, is capable of performing remote authentication in field. Hence, it would allow identifying in-field tampering of PCB, e.g. tampering of interconnects (e.g., metal traces), chips, other active/passive components or ports. Such in-field tampering, for example, includes various instances of modchip (see, e.g., http://en.wikipedia.org/wiki/Modchip) that often requires soldering wires to select traces or pins of chips, thus affecting the property (such as resistance and propagation delay) of the traces. Once the signature is generated, the authentication module operating in the device can verify it itself by comparing it with a stored database or transmit it wirelessly (through radio signal or WiFi) to another device or service (e.g., comprising the signature database) for the purpose of integrity check. Such remote authentication of a PCB inside an electronic device, such as a set-top box, a gaming console, a drone, a home monitoring device or other internet-of-things (IoT) device, can be effective in verifying the integrity of an electronic hardware against physical attacks during field operation, such as the use of modchip mentioned above.

Such remote authentication is done here by exploiting the JTAG logic for autonomous on-demand signature generation from an electronic device in field. It can be accomplished by incorporating low-overhead delay measurement circuitry, such as the parallel scan delay measurement (PSDM) based low-overhead approach disclosed herein, inside and/or onto a PCB, which interfaces with the JTAG logic.

As mentioned, for example, the test system 212 and authentication module 214 of FIG. 18 could be integrated into the PCB 210, and be connected to or access a communications interface (e.g., a network interface) for communicating test results to a remote site, such as corresponding to a manufacturer or other trusted third party (e.g., the signature database 218). The test results may include the signature or the electrical parameter measurements that can be used to generate the signature. For instance, the PSDM based delay measurement circuitry, which can create a fingerprint from the PCB on demand with test clock control. It can then transmit the signal through a wired or wireless communications link (e.g., using radio signal) for verification by a trusted signature database (e.g., database 218). Additionally or alternatively, the circuitry in the PCB 210 can be configured to verify the authenticity and/or detect tampering of the PCB based on the fingerprint that was generated locally or remotely.

Hence, in addition to static validation during system integration, such an approach can be used to dynamically detect tamper of system components on demand in the field during deployment. PSDM hardware can be employed to characterize trace resistance or path delay of traces. In order to prevent potential attack on such remote authentication (e.g., snooping and manipulation of authentication control/data signals), one can perform the authentication through a secure communication channel with a PCB under consideration, such as when circuitry on which the PCB is implemented is connected to network (e.g., via a wired or wireless communications link, such as a WLAN).

In view of the foregoing, a capability of remote authentication of PCB can provide an attractive technology platform for physical tamper detection during operation in many application areas. In particular, it would be beneficial in detecting a physical attack on the electronics of military equipments (e.g., drones) or distributed sensors or gaming consoles, all of which are vulnerable to ‘modchip’ type attacks. In case of the defense industry, for example, it can provide high-level of security against physical tampering of an electronic system during field operation. For vendors that sell gaming consoles, for example, the technology can enable detecting and in turn preventing copyright violation (e.g., illegally running unsupported games) and thereby help protect against unwanted revenue loss.

For purposes of simplicity of explanation, the following examples provide different approaches and implementations of systems and methods to authenticate a PCB and/or detect if a PCB is counterfeit. The disclosed examples, in some circumstances, refer to particular components and materials that may be used; although, the inventions disclosed herein are not limited to the components and materials disclosed herein. Those skilled in the art will understand and appreciate various other components, materials and/or features that may be implemented in practice based on this disclosure that fall within the scope of the invention set forth herein.

### Example 1

### Trace Based PCB Authentication

### Methodology

A method includes selecting which paths of a PCB to measure impedance or other electrical characteristics. As one example, the PCB can be pre-existing circuit boards or boards that are custom designed to identify paths had to be found that fit certain criteria. Most PCBs are made using an FR4 substrate with so-called“1 oz Thick Copper”. This is defined as 1 oz of copper spread over a square foot. Furthermore some PCBs are bathed in a bath of molten tin or gold after fabrication (known in the industry as plating). This will result in the difference in related parameters. For example, under room temperature, gold has a resistivity of 2.44×10⁻⁸ ohm-meters while tin has a resistivity of 1.09×10⁻⁷ ohm-meters, almost an order of magnitude higher.

For example, if the original specifications for a PCB called for gold plating and a counterfeit PCB used cheaper tin plating, the counterfeit PCB will have a higher trace resistance that can be measured. The difference between gold and tin cannot be detected visually because during the assembly of the PCB solder will cover up the gold plating and a PCB with gold plating will look indistinguishable from a PCB with tin plating. However, such differences can be detected by comparing signatures generated as disclosed herein.

While the use of 1 oz copper is standardized across many different manufactures some circuit boards require the use of much more copper, sometime approaching 10 oz copper pours. 10 oz copper is used in many motor drives, for example. If a counterfeiter were to produce a knock-off motor drive they might use 5 oz copper because it is cheaper. 10 oz copper has a much lower resistivity than 5 oz copper. That difference can be measured and would be evident from analysis of signatures generated based on this disclosure.

As disclosed herein, it can be determined whether a PCB is a counterfeit or not by measuring the impedance of a trace that passes through multiple vias. A via is a small hole drilled in a circuit board that, when plated with metal, connects the top layer of copper to the bottom layer of copper. For PCB with more than two layers there are two or more types of vias. A blind via is a via that connects one of the outer layers of the PCB to one of the inner layers. A buried via is a via that connects two of the inner layers together, never surfacing on the outer layers.

Each manufacturer of a PCB tends to start with a similar piece of copper clad and they use their knowledge and skill to make the finished product. Each board house has a different process for etching the copper off of the substrate as well as drilling and plating the vias. These different methods have different intrinsic resistances associated with them. For example, a via that is electrochemically plated onto the FR4 will have a lower resistance than a via that is riveted on, for example.

Finding a good path in a PCB to measure the resistance of is a process that can involve many variables and factors. One factor in choosing a good path is the ability to connect to ends of the path (e.g., can two probes could make good contact with the path). Often times PCB designers coat their PCB in solder mask (a typically green substance that helps keep solder where it belongs) and silkscreen (a typically white paint that helps designate areas of the PCB). Both silkscreen and solder mask have a very high electrical resistivity, preventing an accurate measurement of the trace resistance.

In some types of PCBs (e.g., Terasic DE0 boards) many traces run exclusively in the inner layers of the PCB, using blind and buried vias to travel through the PCB without ever touching the outer exposed layers. Such traces are unavailable for measurement because they are in accessible (without modification to the PCB).

Traces that go to edge connectors are especially useful. Almost all connectors used in products are still throughhole instead of surface mount because of the inherent greater mechanical stability through-hole parts offer compared to their surface mount brothers. It is simple to attach a probe to one of the holes drilled in the board for these connectors. At this point, another end of each selected connectors trace must be found, it will surface far enough from the connector to have a long trace full of vias and surface on a pad that a probe can be attached to.

Sometimes it is simply not possible to find enough connecting traces to gather enough data for a digital fingerprint (e.g., signature). Therefore, in some examples, systems and methods disclosed herein may measure the resistance for a path that comprises two traces that do not connect electrically directly. For example, the USB 2.0 specification states that the impedance between the D+ and D− differential par data lines should be exactly 90 ohms. This resistance is accomplished by routing the differential pair close together and identically through the PCB. For some applications that require tight tolerances on trace impedance matching, PCB manufactures offer a service called “Controlled Impedance”, which itself can operate as a path for the PCB authentication disclosed herein. This service increases the price of the boards drastically and counterfeit PCBs will oftentimes not even try to match the impedance of their differential pair traces.

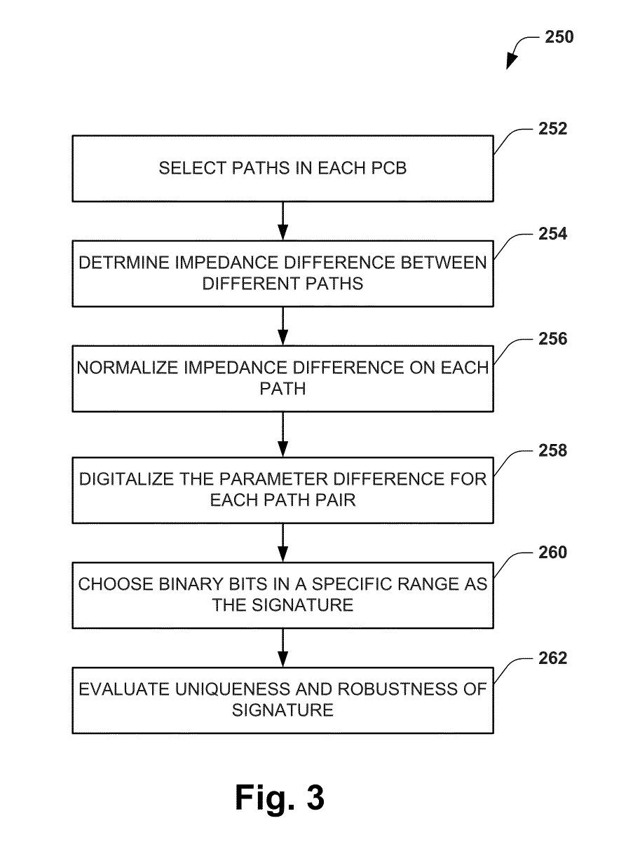

In view of the foregoing, an example of a method 250 of signature generation is shown in FIG. 3. In this example, the impedance of each path is measured and in order to decrease the affect of measurement error due to the equipment calibration or environmental factors, data is collected by averaging a plurality of (e.g., 3 or more) measurements for each path. For example, the impedance can be measured using an HP/Agilent 4263B LCR Meter with the measurement frequency set to 10 KHz. The LCR meter can be self-calibrated before measurement. Additionally open connection correction was done (Leaving the two probes disconnected from everything) as well as short connection correction (shorting the two probes together).

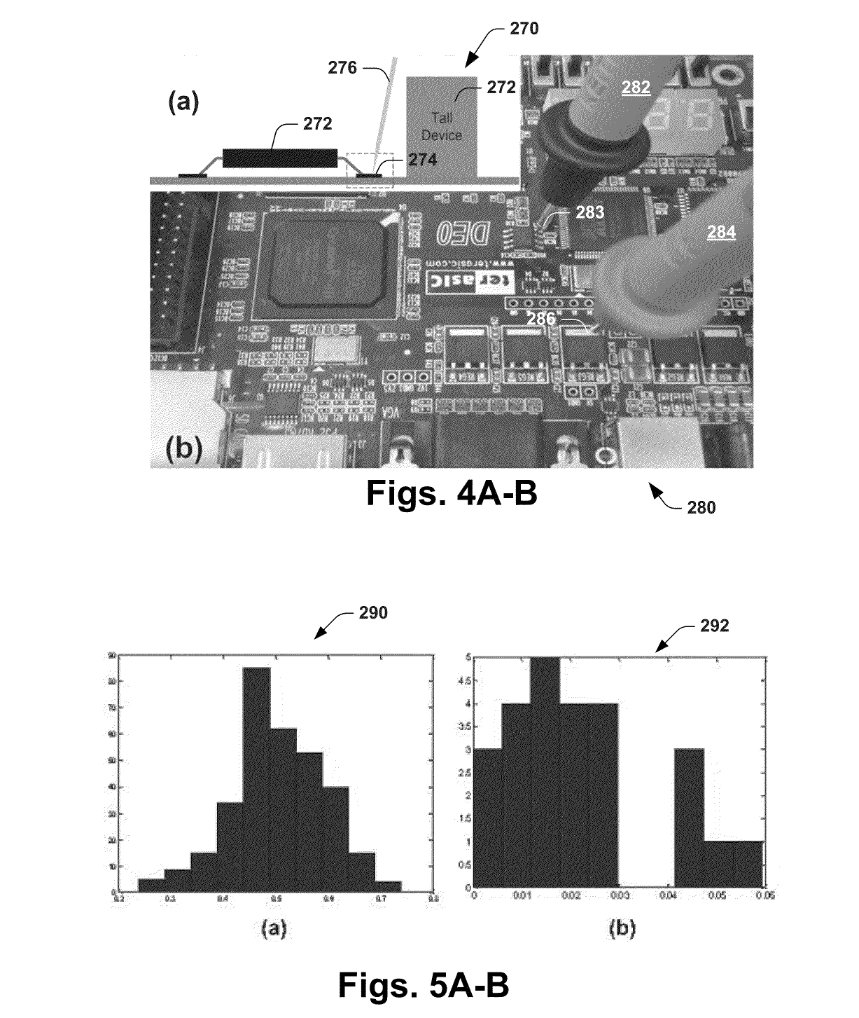

By way of illustration, FIG. 4(a) shows a schematic example of measurement being made for a trace of a PCB 272 to which a plurality of devices have been mounted. As shown in the example of FIG. 4(a), one or more probes 276 can be placed on a pad 274 of the PCB 272 to avoid unwanted contact with other pads on the PCB. Additionally, data can be collected and calculated by averaging the measurement value for a given path a plurality of times for each path to decrease the affect of random variation during each measurement. The reliability and repeatability of the measurement results can also considered by measuring all the boards multiple times during different times of day and/or at different ambient temperatures. Additionally, traces can be chosen from independent PCB traces, meaning that the selected traces did not short to any other signal paths. In the layout of a PCB power traces are usually wider than signal traces to maintain a lower series impedance for the power supply. Therefore, to obtain the best result a visual inspection of the PCB was done to carefully establish which traces to measure.

As a further example, FIG. 4(b) shows a picture of an actual experiment setup that can be used for measuring impedance of electrical paths on a PCB 280. As shown in the Example of FIG. 4(b), a probe 282 is connected to one pad 283 and another probe 284 is connected to another pad 286. A corresponding electrical path extends between the pads 283 and 286, which can be selected for taking one or more measurements, such as disclosed herein.

Referring back to the method 250 of FIG. 3, at 252, paths are selected. For example, at 252 assume totally n paths (n being a positive integer) are selected and a measured impedance on chip c is d^{(c)}=[d₁^{(c)}, d₂^{(c)}, d_{n(c)}]. At 254, an impedance difference between different paths is determined. For example, the impedance difference can be determined similar to an arbiter PUF, such as by making the “race” between 2 paths on the same PCB by subtracting to obtain the difference between 2 paths. Then, the vector Δd^{(c)} is computed, including n(n−1)/2 distance values (e.g., d₁^{(c)}−d₂^{(c)}, d₁^{(c)}−d₃^{(c)}). The determination at 254 thus produces Δd^{(c)}=[Δd₁^{(c)}, Δd₂^{(c)}, . . . , Δdn^{(c)}ₙ₍ₙ₋₁₎].

At 256, the impedance difference between the respective paths is normalized. For example, the normalization procedure is d^{(c)}=(Δdᵢ^{(c)}−minΔd^{(c)})/(maxΔd^{(c)}−minΔd^{(c)}). At 258 the normalized impedance difference is digitalized to a predetermined number of bits. At 260, a corresponding signature is generated from the aggregate bits of the n paths. For example, the signature can be generated by choosing binary bits in a particular range as the signature, such as digᵢⱼ(Δd^{(c)}), where digᵢⱼ(•) is the function to digitalize the elements in Δd^{(c)} and aggregate the bits between the ith and jth bit (i≦j) of each element. In some examples, the digitalized element can be integrated in sequence to generate a signature, which as a result, contains (j−i+1)n(n−1)/2 bits. At 262, the resulting signature can be evaluated for robustness and uniqueness.

### Example Results and Analysis

While on the surface all PCBs seem identical, there are many areas where there are subtle differences between not only manufacturers but also production runs for a given manufacturer. The authentication approach disclosed herein provides a method in which counterfeit PCBs can be detected by electronic means.

In an example test, the method chosen to conduct this test was to measure the impedance of a plurality of traces on a given PCB to establish a baseline impedance measurement profile. Sixteen Arduino UNO R3 boards were bought to establish this baseline. Additionally twenty-five Terasic DE0 boards were bought to further refine the technique on. The measurements were conducted on a HP/Agilent 4663B LCR Meter set to 10 kHz, which was calibrated against a Keithley 2000 series Digital Multi-Meters and verified with a HP/Agilent 34401A Digital Multi-Meters. Both Digital Multi-Meters share almost identical performance specifications with the Agilent meter having a slightly lower temperature drift rating. Both meters cover the same market segment and have the same accuracy (six and a half digits). Keithley Model 5808 Gold-Plated Kelvin Probes were purchased to ensure the highest possible performance of the Digital Multi-Meters.

As an example, the uniqueness and robustness of the signature can be evaluated (at 262) by determining Hamming Distance (HD). Assuming HD_{i,j} stands for the Inter-PCB HD between PCBᵢ and PCBⱼ, the average inter HD for m PCBs, denoted by HD_{avg}, may be calculated as follows:

$${Inter HD}_{avg} = \frac{2}{m ( m - 1 )} {\sum }_{i = 1}^{m - 1} {\sum }_{j = i + 1}^{m} {HD}_{i , j}$$

In an example experiment, HD_{avg} was determine to be about 50:24% based on 25 Terasic DE0 boards evaluated. As a further example FIG. 5(a) shows an example of an inter-PCB histogram plot 290 and FIG. 5(b) shows an intra-PCB histogram plot 292. It has been determined that most of PCB boards have signatures with the inter HD around 50%, such as located between the range from about 25% to about 75%. As a result, the authentication of each PCB can be completed successfully considering good uniqueness of their signatures.

As an example, robustness of a signature can be evaluated at multiple different times at substantially constant temperature. Assuming HD_{p,q} stands for the intra HD of all boards between the qth measurement and qth measurement, the average Intra-PCB HD for n times measurements, denoted by IntraHD_{avg} was calculated by:

$${Inter HD}_{avg} = \frac{2}{n ( n - 1 )} {\sum }_{p = 1}^{n - 1} {\sum }_{q = p + 1}^{n} {HD}_{p , q}$$

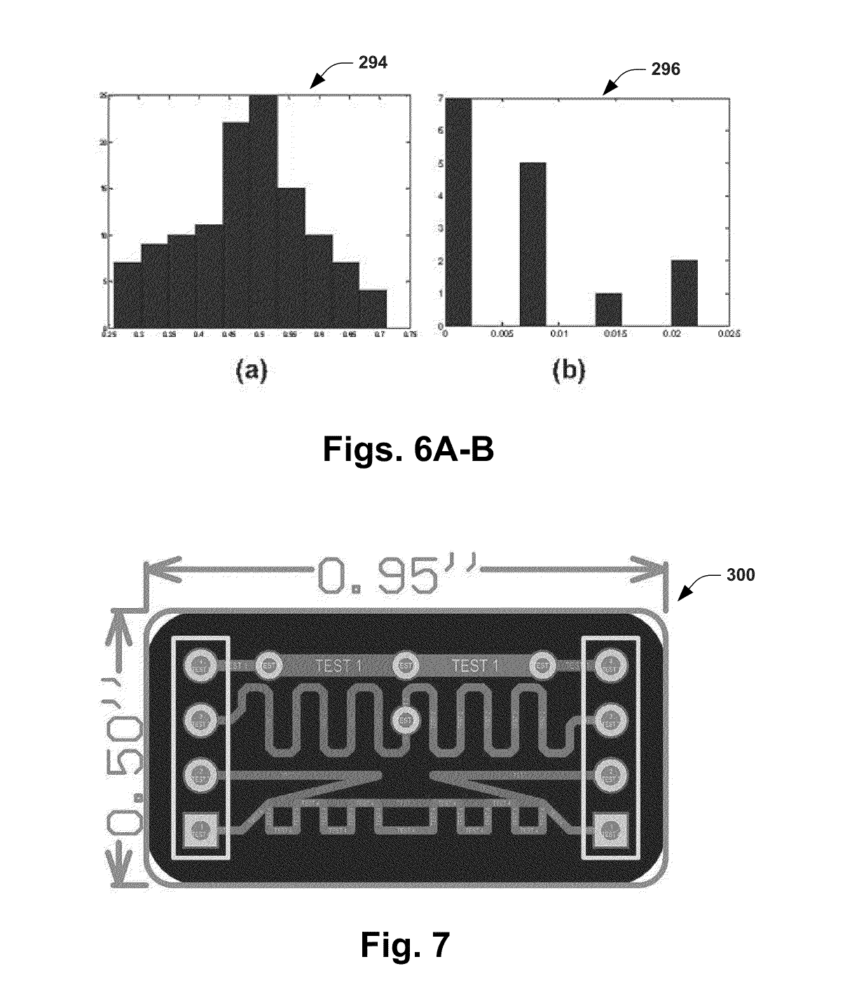

An example plot 294 of a distribution of intra-PCB HD is shown in FIG. 6(b) with the average of 2.14%. Similarly, as another example, the Arduino UNO R3 boards were evaluated in the same way. An example plot 296 of the histogram of Inter-PCB HD for another set of boards is shown in FIG. 6(a) with the average of 47.94% in the range between 25% to 70% and the histogram of Intra-PCB HD is shown in FIG. 5 (b) with the average of 1.06%.

From the examples of FIGS. 5 and 6, the average value of Intra-PCB and Inter-PCB Hamming Distance for both Arduino UNO R3 SMD and Terasic DE0 boards are shown in Table 1.

TABLE 1

| PCB Type | Avg. Intra-PCB HD | Avg. Inter-PCB HD |
|---|---|---|
| Terasic DE0 | 2.14% | 50.24% |
| Arduino UNO R3 SMD | 1.06% | 47.94% |

The security analysis is mainly focused on the cloned PCB problem. The signature is generated from measurements of paths (e.g., copper traces on PCB) with statistical variation inherent in manufacturing processes. To clone a PCB successfully, the attacker needs to have the same equipment and follow the same procedures and requirements as the authentic PCB manufacturer as well as having a similar quality of raw material including the copper foil, laminates substrates and the like. Considering the high cost of equipment and raw material, it is unacceptable for an attacker to clone the PCB using the same high quality materials as the genuine PCB. On the other hand, considering the large number of copper traces on a PCB, a more complex signature can be generated which will increase the difficulty that an attacker faces to get the same signature by cloning. Therefore, the trace impedance based authentication provides an effective and secure method. The end user can identify a cloned PCB by producing its signature and compare it with the manufacturer's database, such as disclosed herein (see, e.g., FIGS. 1-3).

### Designing for Security

The methods described thus far in this paper have focused on identifying cloned or counterfeit PCBs that are already in production. However, the authentication and/or counterfeit detection approaches disclosed herein can be enhanced by integrating circuitry into new PCB designs. For example, it is possible to design a new PCB with traces (and access points) built in to help identify cloned boards in the future. It can be assumed that any cloned PCB will be made using a cheaper method then the original. If the copper in the original circuit board was milled away while the cloned circuit boards copper was etched away then a properly designed board would have traces that were well designed for a mill while being poorly designed for an etching process. For example, both processes of making a PCB will have issues in making a large obtuse angle. A milling process will have issues making the inner section of the angle while an etching process will have issues making the outer portion of the angle. This will affect the measurement properties of the trace when viewed as a micro strip. These and similar difference can be measured and be identifiable from signatures computed based on the teachings herein.

FIG. 7 shows a sample pattern 300 that can be deployed to PCBs taking up less than 0.5 square inches. This example pattern 300 includes of four independent traces, although other numbers of greater or fewer traces could be implemented according to security needs for a given design. Each of the traces extends between respective endpoints, which can be connected to respective pads or other electrically conductive accessible structures. In this particular example, each trace was designed to take advantage of limitations in cheaper PCB manufacturing processes. The top trace, Trace 1, uses four differently sized micro strip transmission lines, each one transitioning between sizes (and layers) with the use of a via. The second trace, Trace 2, simulates a controlled impedance transmission line. The third trace, Trace 3, utilizes sharp angles to expose the aft-mentioned weaknesses in the manufacturing process. The final trace, Trace 4, continues to expose weaknesses in the manufacturing process by having numerous sharp right angle bends in the trace path. If tested at a high frequency then variances in the process will be exposed. Finally the Trace 3 and Trace 4 traces partially overlap on different layers of the PCB, enabling the characterization of crosstalk in the corresponding measurements.

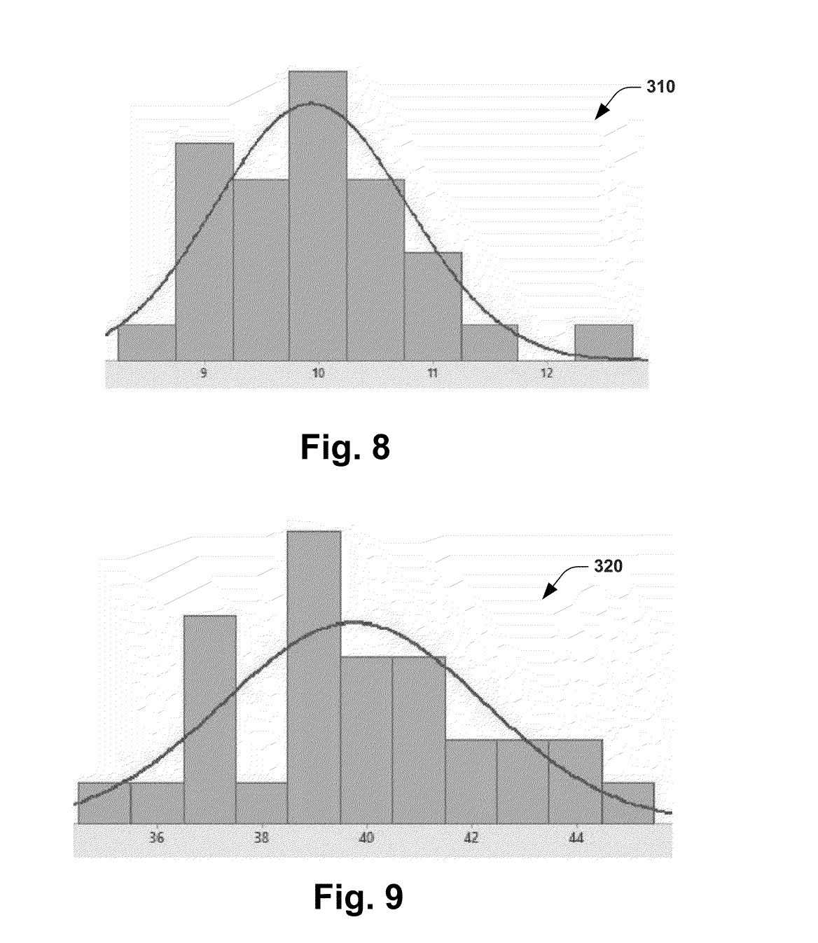

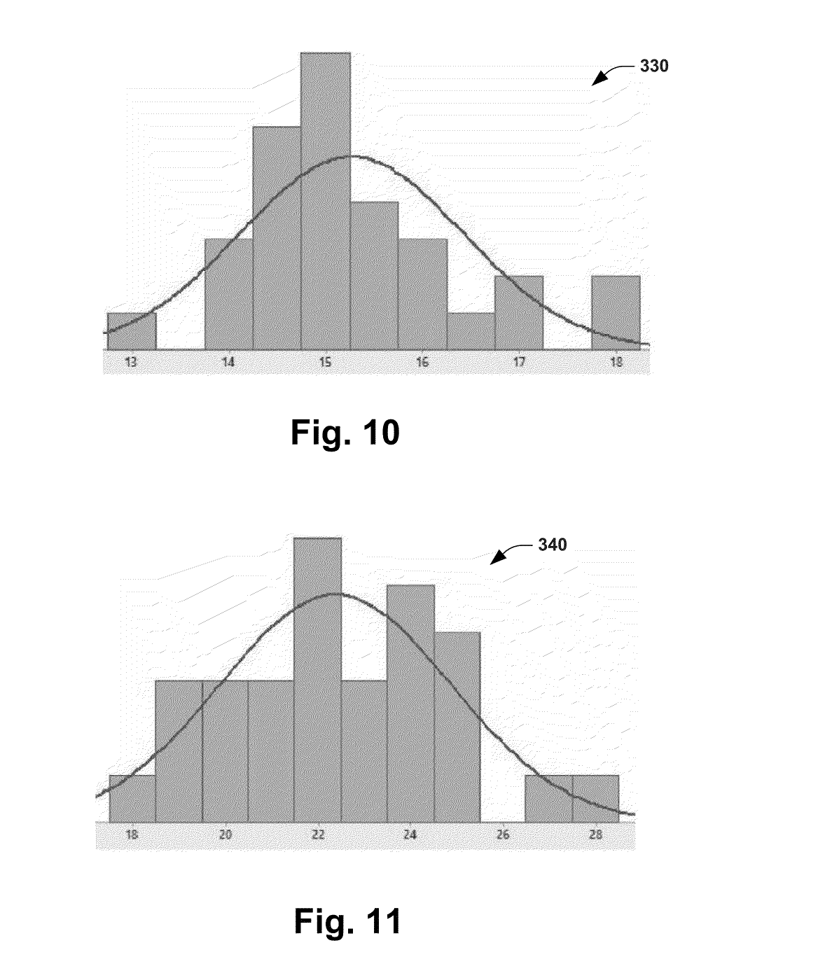

It has been determined that, using the example design in FIG. 7, each of the four traces can be tested using the same methodology described above to produce corresponding impedance measurements. For “Trace 1” the average trace resistance was 9.93 milliohms with a standard deviation of 0.82 milliohms “Trace 2” had an average resistance of 39.76 milliohms with a standard deviation of 2.44 milliohms “Trace 3” had an average resistance of 15.26 millihohms with a standard deviation of 1.13 milliohms Finally “Trace 4” had an average resistance of 22.38 milliohms with a standard deviation of 2.44 millihoms. The histograms of the data, demonstrated at 310, 320, 330 and 340, are shown in FIG. 8, FIG. 9, FIG. 10 and FIG. 11 for Traces 1, 2, 3 and 4, respectively, for the example design in FIG. 7.

As it can be seen each of the four traces in the designed Printed Circuit Board had a distinct signature that was able to be measured by the equipment. This is especially evident with the difference between Traces 2 and 2 (FIG. 9 and FIG. 10) which have a similar histogram profile however Trace 2's measured resistance is almost three times greater than Trace 3's measurement. From these designs it can be demonstrated that an individual trace can be identified from a group.

### Example 2

### JTAG Based PCB Authentication

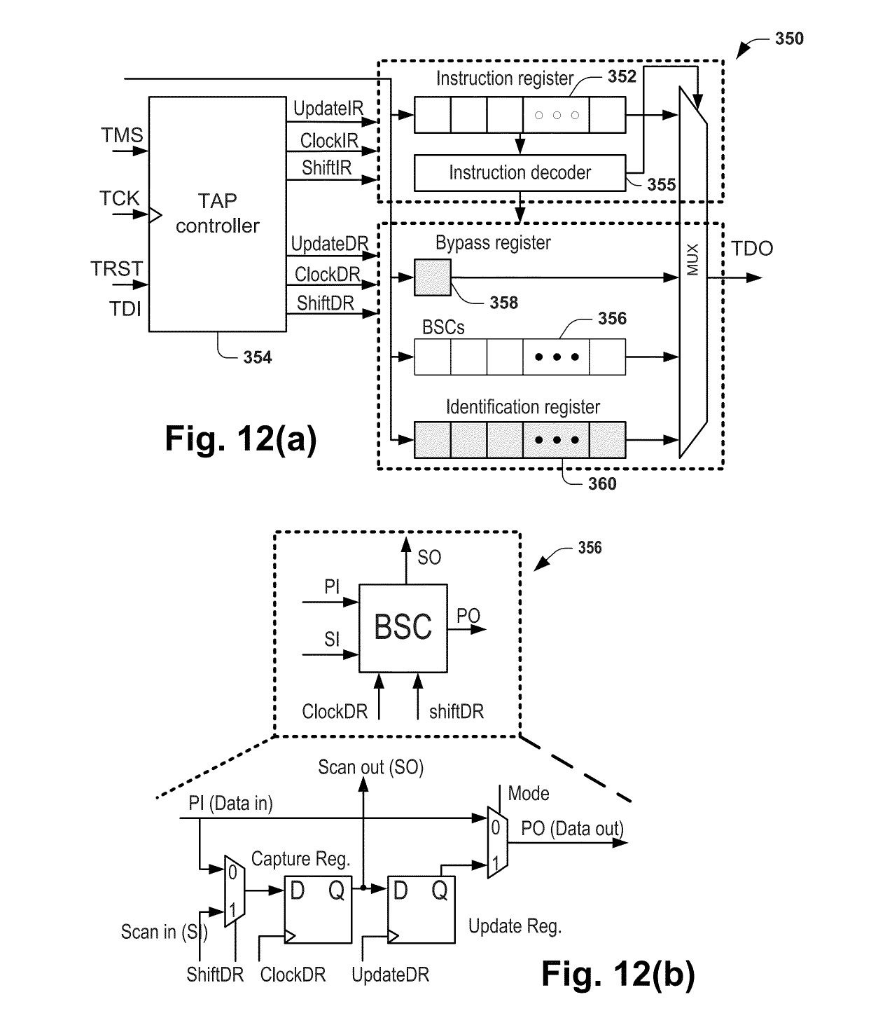

Another approach to PCB authentication can be a JTAG based authentication, such as is disclosed herein with respect to FIGS. 1, 2 and 12-17. An example architecture of JTAG interface 350 is shown in FIG. 12(a) with four input pins (‘TCK’, ‘TMS’, ‘TDI’, ‘TRST’) and one output pin (‘TDO’). For example, the interface 350 includes a TAP controller 354, instruction register 352, instruction decoder 355, boundary-scan register 356, bypass register 358 and identification register 360. The TAP controller 354 can be a finite state machine triggered by the rising edge of clock ‘TCK’, in which the state is changed by the signals from pin ‘TMS’. The outputs of TAP 354 include the clocks and control signals for each register. Hence, with the help of TAP controller 354, the test input vector can be scanned into boundary-scan register, or an instruction code can be input into instruction register. Boundary-scan register is comprised of all the boundary-scan cells (BSCs) in JTAG. Instruction register stores an instruction (e.g., SAMPLE, PRELOAD, EXTEST) and the decoder interprets it and produces a correct multiplexor signal to control the output. Bypass register has only one bit to be the shortest path between ‘TDI’ and ‘TDO’. Identification register (32-bit length) is an optional choice used for loading vendor-related information. At any time, only one register can be connected from ‘TDI’ to ‘TDO’ (e.g., bypass register, boundary-scan register). The selected register is decided by the decoded output of the instruction register. Among all the defined instructions, some are mandatory, such as EXTEST (the selection of boundary-scan register), whereas others are optional (e.g., IDCODE instruction to pass identification register).

The BSCs are connected like a shift register in boundary scan register 356. A BSC can force signal onto pin, capture data from pin, adjacent BSC or core logics. FIG. 12(b) depicts a basic structure of BSC 356. In this example, the BSC 356 includes capture register and update register triggered by two separate clocks ‘ClockDR’ and ‘UpdateDR’ from TAP controller 354. The test vector can be scanned into each BSC by port ‘SI’ and shifted out through ‘SO’. The capture registers can access logic core data or I/O pins via a multiplexer controlled by ‘ShiftDR’; the update registers provide the data to external through I/O pins. Signal ‘Mode’ and ‘ShiftDR’ are generated by the decoding of instruction register. Generally, a BSC can work in four different modes: (1) in normal mode, the data of ‘PI’ is passed directly to ‘PO’, (2) in update mode, the content of the update register is passed through to ‘PO’, (3) in capture mode, the signal of ‘PI’ is routed to the input of capture register, which is captured in the next ‘ClockDR’ cycle. ‘ClockDR’ is a derivative clock of ‘TCK’ by TAP controller, (4) in shift mode, the ‘SO’ of a capture register is passed to the ‘SI’ of the adjacent capture register via a hard-wired path.

### JTAG-Based PCB Authentication

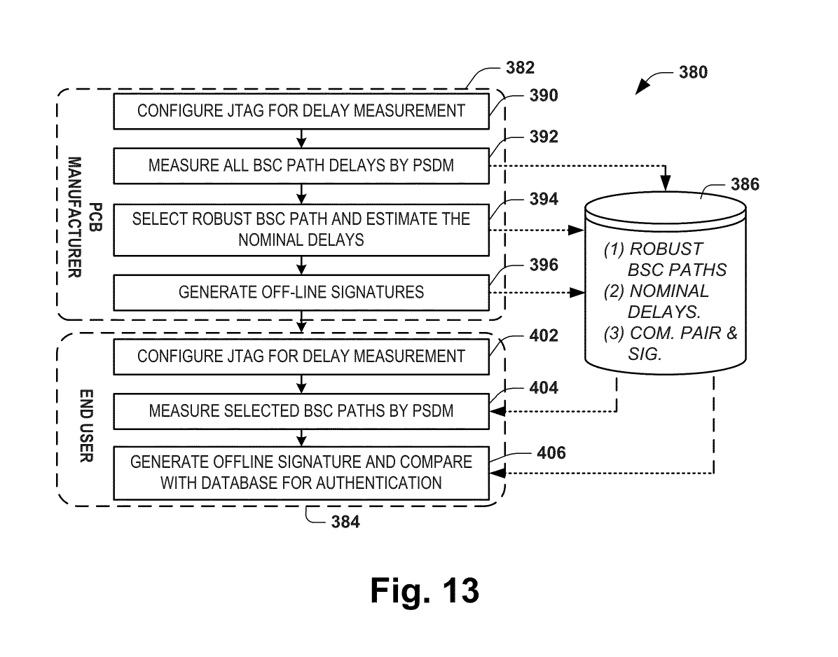

FIG. 13 depicts an example of JTAG-based PCB authentication 380. As shown in FIG. 13, the JTAG-based PCB authentication 380 can be separated into two stages 382 and 384. The first stage 382 includes configuring JTAG for delay measurements, at 390. For instance, PCB manufacture configures the JTAG device in a chip (or several chips) into a proper state (a correct control on the multiplexors in FIG. 12). At 392 the BSC path delays are measured. This can encompass measuring the delay of BSC paths (hard-wired) on all authentic PCBs and identifying robust paths. At 394, the robust BSC paths are selected with the estimation on nominal delays. At 396, the signatures are generated. For example, the signatures can be produced off-line. The locations of BSC paths, the nominal delays as well as signatures (including the comparison pairs disclosed below in the Offline signature generation section) are stored in the database 386.

The other stage 384 of JTAG-based PCB authentication 380 includes procedures implemented end users. At 402, an end user configures the JTAG on the suspected PCB for measurement, which can be the same way. At 404, the delays for the selected BSC paths are measured. Then, at 406, the signature is computed for the PCB. The signature is also compared with the value stored in the database 386. The PCB is judged as counterfeit if the produced signature by the end user is not found in the database. In the following sub-sections, each step in FIG. 3 will be explored further.

### The State of TAP and Instruction for Authentication

The basic idea of proposed authentication is to measure the delay of hard-wired BSC path, which is used to generate unique signature for each PCB. As a result, the TAP controller should be forced into a proper state with holding signal ‘ShiftDR’ in FIG. 12(b) as ‘1’ to make ‘SI’ connect to the input of capture register. In addition, a proper instruction should be loaded into the instruction register to allow the results of BSCs can be output serially through ‘TDO’. As a result, all the capture registers in BSCs can work as a shift register chain.

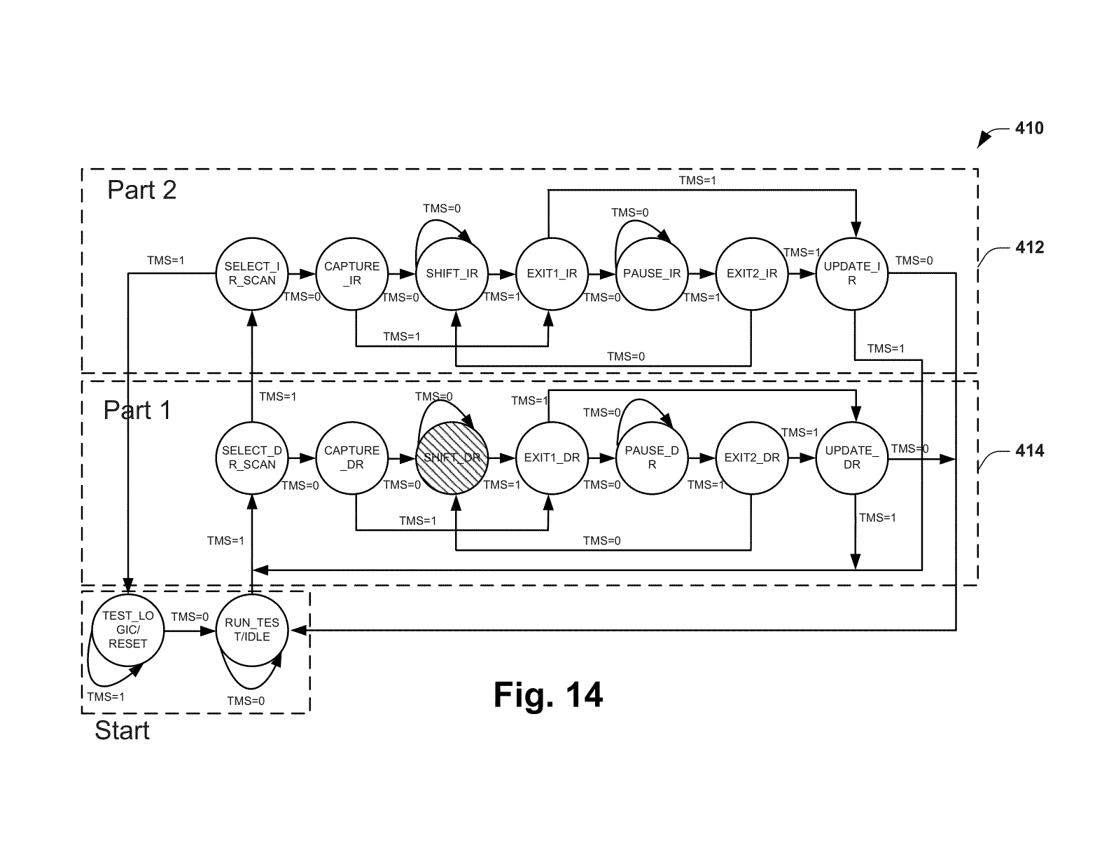

An example, state machine diagram 410 of TAP controller 354 is shown in FIG. 14. The state transition is determined by signal ‘TMS’ on the rising edge of clock ‘TCK’. Generally, they can be separated into two parts, demonstrated at 412 and 414, which direct the test bit sequence into instruction register or data registers (e.g., boundary-scan register). In ‘SHIFT DR’ (indicated by cross-hatching in FIG. 14), the test data registers can shift data from one stage toward its serial output on the rising edge of ‘TCK’. Hence, the test vector can be scanned into the capture registers of BSCs. Among all the mandatory instructions, ‘EXTEST’ is used to test the connections of ICs on a PCB; ‘SAMPLE’ takes a snapshot of the normal operation for the component; ‘PRELOAD’ makes the data load onto the output of boundary-scan register parallelly. For all of them, the test data can be shifted into in boundary-scan register serially through ‘PI’ and the test result can be shifted out through ‘PO’. Hence, the delay measurement of BSC paths is completed when the TAP controller is in state ‘SHIFT DR’ and one of the above instructions is loaded into instruction register.

### Delay Measurement of BSC Path

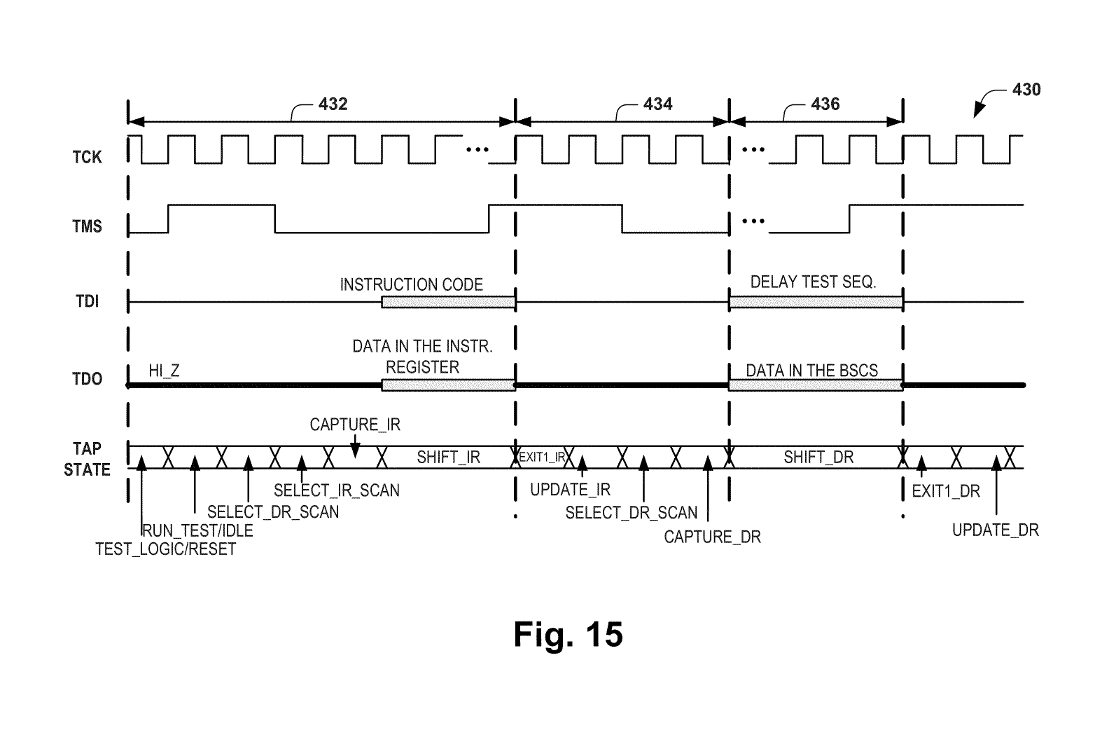

An example of the timing of input and output pins for a JTAG system (e.g., FIG. 12(a)) is shown in FIG. 15. In this example, the timing diagram 430 includes three steps 432, 434 and 436 that can direct JTAG into the state to measure BSC path delay for authentication. The first step 432 is to load ‘EXTEST’ into instruction register. After reset, the state is ‘TEST LOGIC’ which is kept the same when ‘TMS’ holds ‘1’. As shown in the example state diagram 410 of FIG. 14, in the following five cycles, ‘TMS’ is forced as ‘0’, ‘1’, ‘1’, ‘0’ and ‘0’ to make the state machine go through ‘RUN TEST’, ‘SELECT DR SCAN’, ‘SELECT IR SCAN’, ‘CAPTURE IR’ and ‘SHIFT IR’. In state ‘SHIFT IR’, the binary code of ‘EXTEST’ (or ‘PRELOAD’, ‘SAMPLE’) can be shifted into instruction register through ‘TDI’. After decoding, the boundary-scan register is placed between ‘TDI’ and ‘TDO’. The second step is to switch the state of TAP controller from ‘shift IR’ to ‘SHIFT DR’. Similarly, based on FIG. 14, ‘TMS’ inputs ‘1’, ‘1’, ‘1’, ‘0’ and ‘0’ into the in the following five cycles can make the state machine arrive at ‘SHIFT DR’ state, which begins the third step to measure BSC path delays.

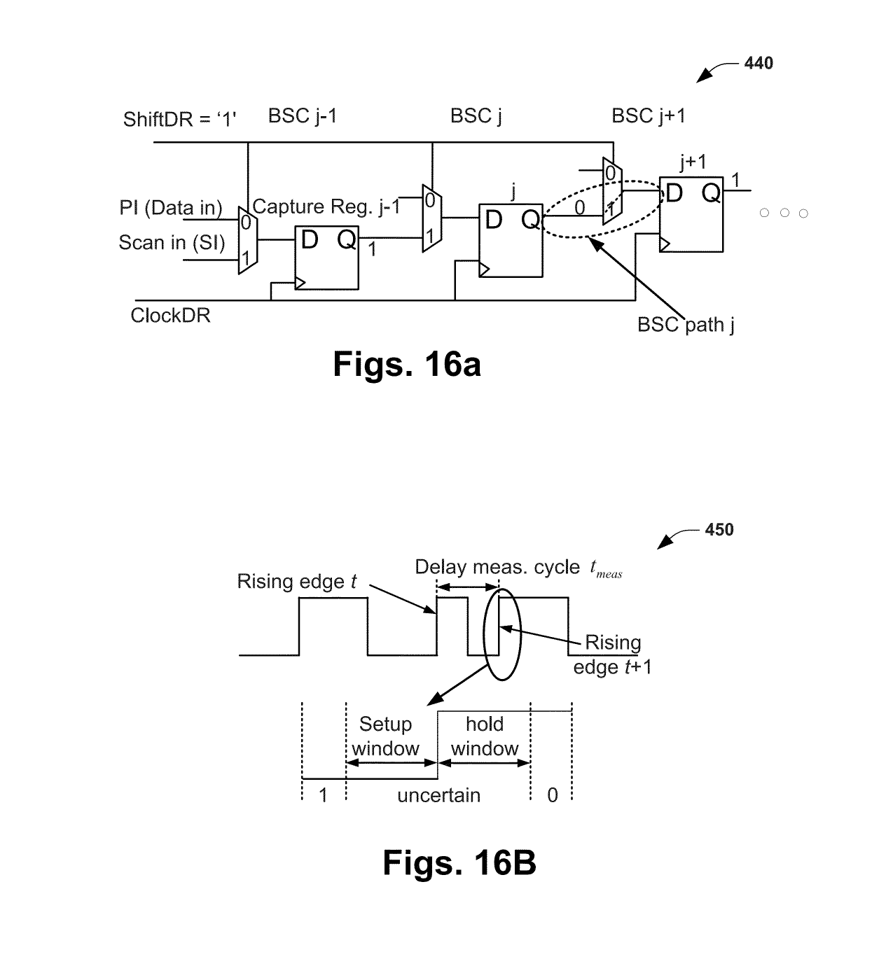

FIG. 16(a) demonstrates an example of a connection of BSCs 440 in the state ‘SHIFT DR’ and FIG. 16(b) shows a corresponding timing diagram 450. For example, in FIG. 16(a), the output of capture register j−1 is connected with input of capture register j, j=1, 2, . . . through a multiplexor, since signal ‘ShiftDR’ is ‘1’ in state ‘SHIFT DR’. Hence, BSCs 440 work as a shift register that can be employed to develop the Parallel Scan Delay Measurement (PSDM) to measure BSC path. The output of register j is initialized as ‘0’. It becomes ‘1’ at the rising edge t of clock ‘ClockDR’ to generate 0→1 transition on the BSC path j. After the interval of tₘₑₐₛ, the rising edge t+1 shows in ‘ClockDR’ of FIG. 16(b). SFF j+1 of PCB i outputs

$${O}_{i , j + 1} = \{ \begin{matrix}1 & {t}_{meas} > {d}_{i , j} \\ 0 & otherwise\end{matrix}$$

The example approach disclosed herein can use two clocks with tunable phase difference to insert a delay measurement cycle and change tₘₑₐₛ as described below. Other methods can also be employed to incrementally or continuously adjust the clock signal during testing. Assume the resolution of tₘₑₐₛ is Δt and the initial period of measurement is tᵢₙᵢₜ. k is called the switch point of path j, if tₘₑₐₛ=tᵢₙₜ+kΔt and tᵢₙₜ(k+1)Δt lead to O_{i,j+1}=0 and 1 respectively. The delay of path j is estimated as:

dᵢⱼ=tᵢₙᵢₜ(k+k+1)Δt/2=tᵢₙᵢₜ(k+0.5)Δt

Note 0→1 transition occurs on the selected BSC paths to measure the delay in parallel, which reduces the test time significantly. The measurement can be repeated to average out the effect of environmental noise, such as temperature and supply fluctuations. An example procedure of PSDM (Algorithm A: PSDM Procedure) is shown below, which can include multiple iterations.

Algorithm A: PSDM Procedure

Input: Location of Nₚₐₜₕ BSC paths.
Initialization: tₘₑₐₛ ← tᵢₙᵢₜ, sw_num ← 0 and k ← 0

while (sw_num < Nₚₐₜₕ)

Generate 0 → 1 transition on all selected
scan paths after the rising edge t.
Produce the rising edge t + 1 after tₘₑₐₛ.
Identify sw new switch points.
sw_num ← sw_num + sw
k ← k + 1

end of while

Output: Path delays as d_{i,j}

At the beginning, tᵢₙᵢₜ should be set to a value that is less than all the BSC path delays to be measured in Algorithm A. As a result, the number of detected switch points, denoted as sw_num, is initialized as zero. In each iteration, the delay-measurement cycle of tₘₑₐₛ identifies sw switch points among Nₚₐₜₕ paths. The switch-point number sw_num is increased by sw. If sw_num is less than Nₚₐₜₕ, it goes into a next iteration with k k+1 and tₘₑₐₛ←tₘₑₐₛ+Δt; otherwise Algorithm A ends and computes the delays as above (d_{i:j}). In Section entitled FPGA EMULATION SETUP, PSDM is implemented in FPGA through sweeping the phase difference of two clocks of low frequency from a phase-locked loop (PLL).

FIG. 16 depicts an example timing diagram 480 showing the timing of pins when applying Algorithm A in measuring BSC path delays. ‘TDI’ and ‘TDO’ are respectively triggered by the rising and falling edge of ‘TCK’. The adjacent two iterations can be interleaved with each other to reduce the test time. For example, loading the test vector of iteration 2 through ‘TDI’ can be done with storing the test results of iteration 1 from ‘TDO’ simultaneously.

Note the delay measurement of BSC paths in PSDM is much simpler than conventional at-speed scan testing on combinational paths. This is due to the following reasons: (1) it avoids the difficulty of test vector generation by an ATPG tool for combinational path sensitization; and (2) it eliminates the need of fast switching on the scan enable signal or enhanced-scan architecture in order to achieve high combinational path delay testability.

### Identification of Robust BSC Path

A PCB manufacturer measures BSC path delays for all authentic PCBs. The experiment results shows that the value of switch point may be changed by 1 or −1 at the room temperature, which in turn results in a unstable delay value in O_{i,j+1}. As a result, we need to identify robust BSC paths under environmental noises by Algorithm B.

Algorithm B: Robust BSC Path Identification

Input: N_{pcb} PCBs and Nₚₐₜₕ BSC paths.
Initialization: (α)_{1xNpath} ← (0)_{1xNpath} , the measured repetition time n

For i = 1 to N_{pcb}

For j = 1 to Nₚₐₜₕ

For k = 1 to 2

Measure path k by n times.
Decode rep. code (n, 1) as d_{i,j,k}.

EndFor

d_{i,j}← d_{i,j,1}
If d_{i,j,1}≠ d_{i,j,2}

α(j) ← α (j) + 1

EndIf

EndFor

EndFor

Output: {d_{i,j}} and robust indicator α

In the example of Algorithm B, the delay of the jₜₕ BSC path is measured n times according to Algorithm A. Then its delay d_{i,j,1} (regarded as d_{i,j}) is obtained by decoding a (n, 1) repetition code. For example, if n=7 with the delay vector (1, 2, 1, 2, 2, 2, 2), the delay of path j is decoded as 2, since it has the largest probability. Such procedure is repeated one more time and we obtain d_{i,j,2}. If d_{i,j,1}≠d_{i,j,2}, it means path j is not stable in PCB i. Hence, the robust indicator is updated as a(j)←a(j)+1. When Algorithm B is completed on all the PCBs, we can obtain the delay matrix on each BSC path as {d_{i,j}}, as well as the vector. To ensure a stable signature, we only select path j with small value a(j) under room (and/or high) temperature. Based on {d_{i,j}}, we estimate the nominal delay Dⱼ (j=1, 2, . . . , Nₚₐₜₕ) of path j by averaging as

$${D}_{j} = {\sum }_{i - 1}^{{N}_{pcb}} {d}_{i , j} / {N}_{pcb}$$

The robust path locations and corresponding nominal delays are stored in the database, which are employed by both PCB manufacturer and end users to produce the signature.

### Off-Line Signature Generation

The signature can be generated off-line after obtaining all the delay values. The PCB manufacture and end user calculate it based on the nominal value {D₃} (j=1, 2, . . . , Nₚₐₜₕ). For PCB i (i=1, 2, . . . , N_{pcb}), the delay d_{i,j} of path j is updated as

d_{i,j}←d_{i,j}−Dⱼ

After (4), the mean value of d_{i,j}(j=1, 2, . . . , Nₚₐₜₕ) becomes zero. This means the differences of selected BSC paths on the nominal corner are eliminated. In addition, the remaining deviation from zero is due to the process variation during manufacturing. Hence, when generating signature bit s, path j and j′ can be treated as

$$s = \{ \begin{matrix}1 & {d}_{i , j} > {d}_{i , j} \\ 0 & else\end{matrix} where j \neq {j}^{′} .$$

Here, the comparison pair (j, j′) should be stored into database along with the signature of each PCB. One reason to choose off-line method is that the manufacturer can select those BSC paths to generate signatures with high quality and implement additional security in the selection of such paths, for example. The above generation of the signature bit s is similar to the signature generation of RO-PUF. The main difference is that the structure of each ring oscillator is required completely identical in RO-PUF, because of the requirement on the same nominal frequency. However, in our off-line signature generation method, all the stable BSC paths can be employed as the source of signature generation. As a result, it can incorporate more stable BSC paths to generate the signatures.

### Authentication by System Integrator

The authentication of a suspected PCB is completed by end user. First, the location of robust BSC paths is obtained from the database of manufacturer. The actual delay of each selected BSC path in the PCB is measured according to Algorithm A and the stable value is extracted after decoding the (n, 1) repetition code. Based on the same database, the delay update noted above (d_{i,j}←d_{i,j}−Dⱼ) is carried out to eliminate the affect from nominal delay. At last, end user produces a signature (according to generation of signature bits s) with knowing the selected comparison pairs. The PCB is regarded as authentic, if the obtained signature matches the database. The PCB is considered counterfeit if the signatures do not match.

### FPGA Emulation Example

The structure of BSCs in FIG. 12(b) can be implemented using the logic resources in FPGA. No gates are inserted between two adjacent BSCs, and therefore the manufacturing variation on wire contributes most to the measured delay variation. It matches the situation in real JTAG, and thus the emulation results provide a good validation for the application.

As part of the setup, for the example FPGA, the steps 432 and 434 of FIG. 15 have been omitted since they relate to setup according the particular JTAG architecture. FIG. 18(a) shows an example architecture 490 that includes a PSDM 492 and BSC path 494, such can be implemented corresponding to step 436 of FIG. 15. The PSDM 492 provides clock ‘TCK’, ‘TDI’ and ‘TDO’ to the chips of JTAG on a PCB. A PLL outputs three clock ‘c0’, ‘c1’ and ‘c2’ of period tₒᵣᵢ. The phase of ‘c1’ is tunable, while the phases of ‘c0’ and ‘c2’ are fixed. ‘c0’ and ‘c1’ are the inputs of clock-switch module to produce ‘TCK’. The phase shift controller outputs the signals with the timing required by the PLL to change the phase of ‘c1’. The main controller manipulates sweeping the phase shift of ‘c1’ according to Algorithm A, such as disclosed in the above section entitled “Delay Measurement of BSC Path.” ‘TMS’ is the alternative ‘0’ and ‘1’ sequence to generate 0→1 transition on those selected BSC paths. Each switch point can be identified by the post-processing module and stored into a memory to estimate delay as disclosed herein. Algorithm A mentioned above includes multiple iterations to identify the switch point of each scan path.

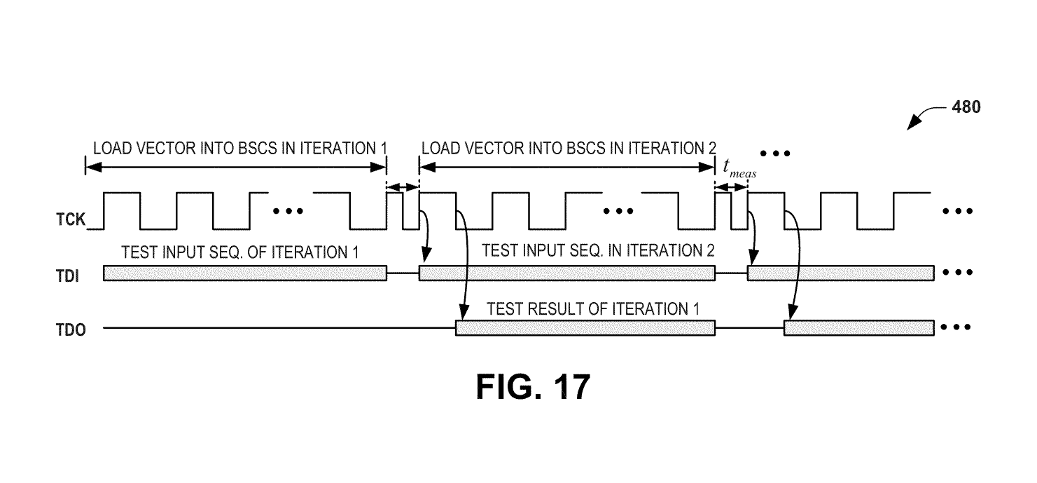

FIG. 18(b) is a timing diagram 500 showing example of timing for the 490 demonstrated in FIG. 18(a) of generating a delay-measurement cycle of period tₘₑₐₛ into ‘TCK’ in an iteration. ‘c2’ is a delayed version of ‘c0’ by 0:5tₒᵣᵢ. The signal ‘sel_c2’ is synchronized with the rising edge of ‘c2’. Initially, it is set as logic level ‘0’. Hence, ‘sel’ is also ‘0’ that allows ‘c0’ to pass the multiplexor. After the rising edge A2 of ‘c2’, the main controller sets ‘sel_c2’ as logic level ‘1’. The rising edge A0 of ‘c0’ generates the rising edge A3 of ‘TCK’ and then ‘TCK’ holds ‘1’. In addition, A0 triggers the DFF in the clock-switch module to sample ‘sel c2’. As a result, ‘sel’ becomes ‘1’ after a small delay due to the red line in FIG. 17(a). Then ‘c1’ passes the multiplexor to reset ‘TCK’ as ‘0’. With the arrival of the rising edge A1 of ‘c1’, ‘TCK’ becomes ‘1’ again that generates the rising edge A4. Hence, two rising edges (A3 and A4) in ‘TCK’ form a delay-measurement cycle of the period tₘₑₐₛ. After A4, ‘sel c2’ becomes ‘0’ and ‘c0’ passes as the output of the multiplexor for a new iteration.

In FIG. 18(a), the post-processing module checks whether all switch points are found. If there is less than desired number of paths, it means some path delays are longer than the current tₘₑₐₛ and a new iteration is required. In, the Hspice simulation shows tₘₑₐₛ≈t_{d}, where t_{d} is the interval between the rising edge A0 and A1. The value of t_{d} can be tuned by shifting the phase of ‘c1’ with the step Δt. In the new iteration, the phase shift controller leads to t_{d}←t_{d}+Δt. Hence, a new delay-measurement cycle, as shown in FIG. 18(b) is generated with an updated tₘₑₐₛ increased by Δₜ. The iterations continue until all the switch points for each of the path (e.g., each BSC) are identified.

Depending on implementation of the system 490, there is an achievable range of tₘₑₐₛ. Assume the delay between A0 and the time that ‘sel’ becomes ‘1’ (due to the red and blue line) is tₘᵢₙ. t_{d}<tₘᵢₙ should be satisfied to pass A1 to ‘TCK’ in the delay-measurement cycle, which requires tₘₑₐₛ>tₘᵢₙ in PSDM. Note the test results from ‘TDO’ are synchronized with the falling edge of ‘TCK’. The test results from ‘TDO’ are available on the first falling edge after A4. To store the results correctly into the memory under the rising edge of ‘c2’, tₘₑₐₛ should be less than tₒᵣᵢ during the phase sweep process.

As an example, the hardware resources of implementing PSDM in Cyclone III (3C16F484C6) includes 356 logic elements (2% total combinational functions), 208 register (1% dedicated logic registers) and 2048 memory bits(<1% memory bits). The memory bits are used to store the switch points in the post-processing module. Hence, PSDM has low-complexity implementation and is suitable to the JTAG-based authentication of PCBs.

Since each authentic PCB can generate a unique ID (e.g., signature) through measuring BSC path delays, as disclosed herein, the end user can identify a cloned PCB by producing its signature and comparing it with the database of signatures provided by manufacturer. For a recycled PCB, it can be detected from two methods based on unique signature. First, the aging effect due to Negative Biased Temperature Instability (NBTI) may lead to a big variation of signature that makes the signature unmatched with the database. Or the manufacturer can record the signatures of sold PCBs and publish them for end user's further evaluation.

Unclonability of signatures in a PCB can further be analyzed. First, it can be assumed that an attacker can only buy the chips to clone a PCB, since the design and manufacture of a chip by himself means an unacceptably high cost. The signature is generated from the BSC path delay of chips with statistical variation inherent in manufacturing processes. To clone the authentic PCB successfully, an attacker should find all the chips used on the PCB, which have the identical delays of BSC paths to those on an authentic PCB. Nowadays, each chip may have more than 1000 BSC paths, the probability that the chip manufacturer can produce two authentic chips with identical delay for all the BSC paths is extremely low (e.g., 2⁻¹¹⁰⁰). Moreover, with the increased number of chips on a PCB, such cloning work becomes more and more infeasible. Hence, the JTAG-based authentication is an effective and secure method.

### Application of JTAG-Based Authentication

When implementing the JTAG-based authentication, there are some notes for PCB manufacturer and end user. First, the clock ‘TCK’ should not be fixed on the board. Instead, it incorporates a wire jumper to support the change of ‘TCK’ by end user. Such change is very minor on the layout of PCB with negligible cost. During the authentication, end user should control ‘TCK’ to provide the tunable delay measurement cycle from outside. Note PSDM is a low-overhead method to measure the delay on the scan. Other methods can also be applied to complete the same task, such as the clock frequency sweeping. No matter what methods they employ, the overhead on the side of end user is virtually zero, since PSDM can be implemented on an FPGA development board. As discussed above, the robustness of signature can be improved significantly from the two phases. First, the authentication by end user can be proceeded in a room with a constant temperature (e.g., 25 degrees Celsius), which is the same to the environment that PCB manufacturer has already done. Second, with a better resolution of delay measurement cycle, the change of path delay due to temperature can be traced better, which reduces the number of flipped bits significantly. As a result, JTAG-based authentication would have a wide application in the area of PCB authentication due to its low overhead and robustness.

Possible Extension to PCBs without BSC

The delay measurement on BSC paths is the source for JTAG-based authentication. However, JTAG may not be existing on a PCB; we can obtain other information for authentication in that case. For example, the post-manufacturing resistance and capacitance of wires on the PCBs would be different due to the process variation, such as disclosed herein. If the delay of signal propagation on wire or other parameters (e.g., resistance) is characterized accurately, the proposed off-line signature generation method can still be applied in such scenario to generate a unique signature for each PCB.

The approaches disclosed in the second example provide a novel low-overhead approach for counterfeit PCB detection. It utilizes random variations in boundary-scan path delay in the industry-standard JTAG-based DFT structure. The approach disclosed herein scheme can produce high-quality signatures (with good uniqueness and reproducibility) for PCBs and can be used to reliably authenticate them. The approach disclosed herein also provides an efficient low-overhead method to measure the BSC path delays at fine resolution. The approach disclosed herein can be used to adjust the quality of signature can be improved through choice of BSC paths, which can be done during off-line signature generation. Since the authentication approach does not require specialized hardware resources or design modifications, it can be applied to any legacy PCB that incorporates boundary scan. Hence, the proposed authentication approach provides an effective way to mitigate supply chain risk associated with counterfeit PCBs. Future work will include further validation with experiment using commercial PCBs equipped with JTAG and enhancement of PSDM to improve its resolution.

What have been described above are examples. It is, of course, not possible to describe every conceivable combination of components or methods, but one of ordinary skill in the art will recognize that many further combinations and permutations are possible. Accordingly, the invention is intended to embrace all such alterations, modifications, and variations that fall within the scope of this application, including the appended claims. Where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, the term “including” means including but not limited to. The term “based on” means based at least in part on.

From the above description of the invention, those skilled in the art will perceive improvements, changes and modifications. Such improvements, changes and modifications within the skill of the art are intended to be covered by the appended claims. All references, publications, and patents cited in the present application are herein incorporated by reference in their entirety.

What is claimed is:

1. A method for authenticating a printed circuit board (PCB), comprising:
measuring electrical parameters for each of a plurality of paths of the PCB;
determining values based on the measured electrical parameters for each of the plurality of paths of the PCB;
generating a signature for the PCB based on at least a portion of the determined values to uniquely identify the PCB.

2. The method of claim 1, wherein measuring electrical parameters further comprises:
connecting a pair of probes to spaced apart electrical conductors of the PCB corresponding to a given one of the plurality of paths; and
measuring electrical impedance between the pair of probes;
storing the measured electrical impedance in memory; and
repeating the connecting, measuring and storing for each of the remaining paths, the determined values being derived for each of the plurality of paths based on the measured electrical impedance for each respective path.

3. The method of claim 2, wherein determining values further comprises computing each of the determined values as a mathematical function of the measured electrical impedance for at least two paths.

4. The method of claim 1, wherein determining values further comprises normalizing each of the determined values to a common predetermined scale.

5. The method of claim 1, wherein at least the given one of the plurality of paths comprises a length of an electrically conductive trace extending along at least one layer of the PCB.

6. The method of claim 5, wherein at least some of the electrically conductive traces pass through multiple vias formed through respective layers of the PCB.

7. The method of claim 1, wherein the PCB is a populated PCB that includes mounted electrical components.

8. The method of claim 7, wherein at least some of the mounted electrical components include Joint Test Action Group (JTAG) compliant components comprising boundary scan cells, at least one of the plurality of paths includes the boundary scan cells, wherein measuring electrical parameters further comprises:
connecting a test probe to at least one JTAG port on the PCB; and
determining a time associated with propagating signals through the plurality of paths based on signals detected at the at least one JTAG port via the test probe.

9. The method of claim 8, wherein determining the time further comprises determining a time delay for propagating a signal through a path residing in a given one of the components and a time delay for another path residing in at least one other of the components or at least one electrically conductive trace extending through the PCB.

10. The method of claim 9, wherein the path residing in the given one of the components comprises a connection between a pair of boundary scan cells.

11. The method of claim 10, wherein determining the time delay further comprises:
providing a test clock signal to the given one of the components, the test clock signal employing adaptive clocking to adjust a frequency of the test clock signal used for propagating predetermined test data through the path residing in the given one of the components.

12. The method of claim 11, wherein the adaptive clocking decrements the frequency of the test clock signal over a plurality of test intervals, the time delay for propagating the test clock signal through the path residing in the given one of the components being determined based on detecting a failure to propagate the predetermined test data through at least a portion of the path residing in the given one of the components due to the test clock frequency being too low.

13. The method of claim 1, wherein the signature is a unique signature for the given PCB to represent physically unclonable functions of the given PCB.

14. The method of claim 1, further comprising evaluating authenticity of the PCB based on the generated signature.

15. The method of claim 14, further comprising storing each of the generated signatures in at least one database,
wherein evaluating authenticity further comprises comparing the generated signature with the signatures stored in the database to ascertain whether or not the PCB is authentic.

16. The method of claim 14, wherein the evaluating is performed remotely via accessing the database via a communications link based on a signature generated from at least one of one of measurement circuitry integrated into the PCB or test circuitry connected to the PCB.

17. The method of claim 1, further comprising selecting the plurality of paths and performing the measuring of the selected paths of the PCB in a predetermined sequence.

18. The method of claim 17, wherein determining values further comprises digitizing each of the determined values to a corresponding binary word representing a corresponding a respective path of the plurality of paths, and
wherein generating the signature for further comprises concatenating a selected subset of the determined values in a predefined sequence to provide the signature to uniquely identify the PCB.

19. A method comprising:
for a plurality of paths of a printed circuit board (PCB):
selecting one of the plurality of paths of the PCB;
connecting a pair of probes to spaced apart electrical conductors corresponding to the selected path;
using the connected probes to measure electrical impedance for the selected path; and
determining a value for the selected path based on the measured electrical impedance;
generating a signature based on at least a portion of the determined values for the plurality of paths to uniquely identify the PCB; and
storing the generated signature.

20. The method of claim 19, wherein the PCB is a given PCB, the method further comprising:
storing the generated signature to a remote site comprising a database of signatures generated for each of a plurality of different PCBs; and
determining authenticity of the given PCB and/or detecting in-field tampering of the given PCB based on evaluating the generated signature with respect to the database of signatures.

21. A method comprising:
providing a populated printed circuit board (PCB) that includes a plurality of Joint Test Action Group (JTAG) compliant components mounted to the PCB, the PCB including a plurality of electrically conductive paths between boundary scan cells within at least some of the components and paths connected between different ones of the components;
connecting a test probe to a JTAG port on the PCB;
measuring a temporal parameter for each of a plurality of paths based on signals detected at the JTAG port via the test probe; and
generating a signature based on the measured temporal parameters for a selected set of the plurality of paths to uniquely identify the PCB.

22. The method of claim 21, wherein the PCB is a given PCB, the method further comprising:
storing the generated signature to a remote site comprising a database of signatures generated for each of a plurality of different PCBs; and
determining authenticity of the given PCB and/or detecting in-field tampering of the given PCB based on evaluating the generated signature with respect to the database of signatures.
